(19) United States
(12) Patent Application Publication
(10) Pub. No.: US 2008/0291608 A1
(43) Pub. Date: Nov. 27, 2008

(54) Auxiliary Pad For Notebook PC

(76) Inventor: Eagle Fan, Hsinchu (TW)

Correspondence Address: LIN & ASSOCIATES INTELLECTUAL PROPERTY, INC., P.O. BOX 2339, SARATOGA, CA, 95070-0339, US

(21) Appl. No.: 11/752,924

(22) Filed: May 24, 2007

(51) Int. Cl. H05K 7/00

(52) U.S. Cl. 361/679

(57) ABSTRACT

An auxiliary pad for notebook PC is provided, including a retractable pad, a connection arm, and an engaging plate. The connection arm is connected to the side of the retractable pad. The engaging plate can be engaged and disengaged from the tip of the connection arm. The retractable pad can be placed underneath the notebook PC so that the notebook PC will tilt a small angle to provide convenient use and improved heat dissipation. The connection arm includes a plurality of connection elements that can be adjusted to hold a peripheral device in the air. The engaging plate can be fixed to the back of an Internet phone, a telephone seat, or other electronic peripherals to provide more convenience in using the notebook PC.

### FIELD OF THE INVENTION

The present invention generally relates to a peripheral apparatus for notebook PC, and more specifically to an auxiliary pad for providing a more user-friendly environment to the notebook PC users.

### BACKGROUND OF THE INVENTION

The notebook PC has become the necessity for many users in various working environment. With the wireless technology advancement, more and more venues provide the wireless Internet access to the notebook PC users to realize the concept of mobile office for business, and instant information access for general Internet users. On the other hand, the Internet phone is gaining popularity become of the speed and the price tag. To further enable the ease of use of Internet phone, the Internet phone is preferably located closer to the notebook PC so that the user can have easy access to both. The present invention targets the above need as well as addressing the heat dissipation issue that is common faced by notebook PC.

### SUMMARY OF THE INVENTION

The primary object of the present invention is to provide an apparatus for more convenient use of notebook PC. With the structure of the present invention placed under a notebook PC, the notebook PC will tilt a small angle so that the user can use the notebook PC more easily and the notebook PC can also dissipate the heat easily. The present invention also includes a connection arm able to hold a peripheral device, such as Internet phone, mobile phone, or a phone seat, close to the notebook PC so that more convenience can be achieved in using the notebook PC.

Another object of the present invention is to provide an auxiliary pad applicable to a variety of notebook PCs. As the size of notebook PCs varies, the present invention includes a retractable pad that is adjustable to suit various sizes so that the notebook PC can sit firmly and stably on the retractable pad.

Yet another object of the present invention is to provide an auxiliary pad that is easy for storage. The present invention can be easily stored when folded into a small block. This also provides a higher portability.

Yet another object of the present invention is to provide an auxiliary pad that fits the notebook PC user. The connection arm for holding the peripheral device is connected to the side of the retractable pad, and can be placed on either left side or right side to fit the user's habit.

To achieve the above objects, the present invention provides an auxiliary pad for notebook PC, including a retractable pad, a connection arm, and an engaging plate. The retractable pad has a long shape with a top contact surface and a bottom contact surface. The top contact surface is not parallel to the bottom contact surface. Therefore, when the bottom contact surface is placed on a horizontal surface, the top contact surface is tilted a small angle. The connection arm is connected to the side of the retractable pad. The connection arm includes a plurality of connection elements that can be adjusted to hold a peripheral device in the air. The engaging plate can be engaged and disengaged from the tip of the connection arm. The engaging plate can be fixed to the back of an Internet phone, a telephone seat, or other electronic peripherals. The present invention provides the notebook PC user more convenience in using the notebook PC.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a three-dimensional view of the present invention;

FIG. 2 shows a side view of the present invention;

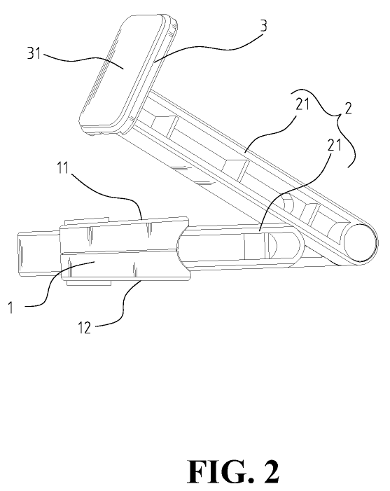

FIG. 3 shows an exploded view of the present invention;

FIG. 4 shows a three-dimensional view of the present invention from a different angle;

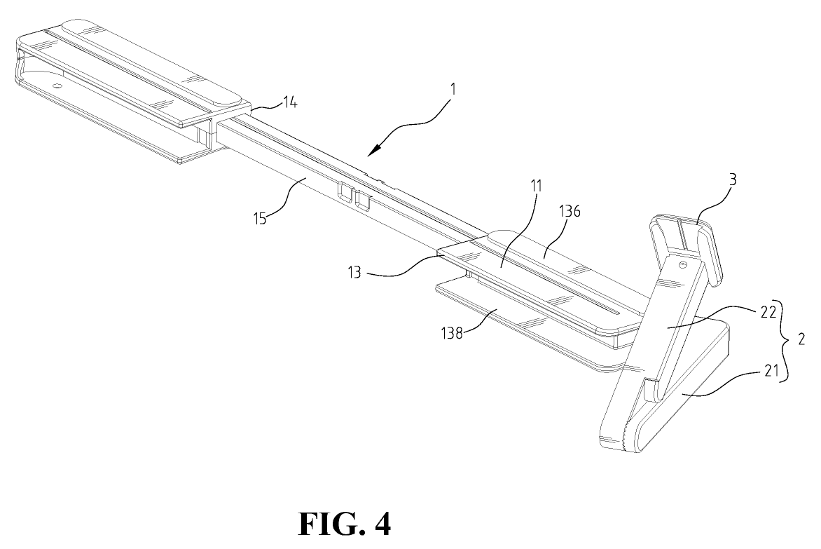

FIG. 5 shows a partial enlarged exploded view of the present invention;

FIG. 6 shows an application of the present invention;

FIG. 7 shows a schematic view of the present invention when during folding for storage;

FIG. 8 shows a schematic view of the present invention when folded for storage; and

FIG. 9 shows a second embodiment of the present invention.

### DETAILED DESCRIPTION OF THE PREFERRED EMBODIMENTS

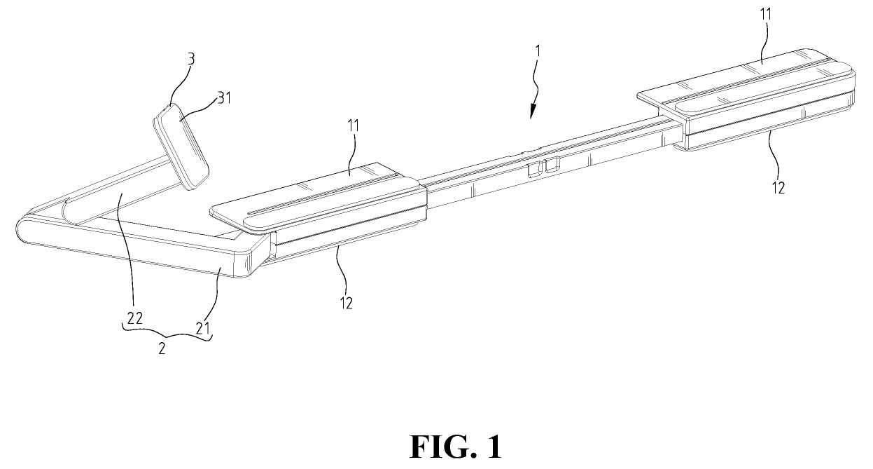

FIGS. 1 & 2 show a three-dimensional view and a side view of the present invention, respectively. An auxiliary pad for notebook PC includes a retractable pad 1, a connection arm 2, and an engaging plate 3. Retractable pad 1 has a long shape. A fixed-size pad can also be used instead of a retractable pad in the present invention. The following embodiment uses a retractable pad to show more usage flexibility. Retractable pad 1 has a top contact surface 11 and a bottom contact surface 12. Top contact surface 11 is not parallel to bottom contact surface 12 so that when retractable pad 1 is placed horizontally, top contact surface will tilt a small angle. Retractable pad 1 is to be placed underneath the bottom of the notebook PC close to the rear end where the screen is. Therefore, when retractable pad 1 is placed, the keyboard of the notebook PC will also tilt a small angle, which is easy for typing. In addition, a small space is created when the retractable pad is used so that the heat dissipation is improved. Connection arm 2 includes a plurality of connection elements. In the present embodiment, connection arm 2 includes a first connection rod 21 and a second connection rod 22. First and second connection rods 21, 22 are connected to form a supporting arm. In the present embodiment, one end of first connection rod 21 is connected to the side of retractable pad 1, and the other end of first connection rod 21 is connected to one end of second connection rod 22. The other end of second connection rod 22 can be engaged to and disengaged from engaging plate 2. Although the present embodiment shows only two connection rods, the present invention can also be designed to include 3 or more connection rods, and the shapes and the sizes of the connection rods can be changed according to the required positions and the angles. Also, all the connection rods are connected in the manner that the connection rod of the previous stage is connected to the connection rod of the next stage. The first connection rod is connected to the retractable pad, and the last connection rod is connected to the engaging plate. Engaging plate 3 is for providing connection to a peripheral device, such as Internet phone, a telephone seat, or other electronic peripheral devices. By adjusting the position and the angles of the connection rods, connection arm 2 can hold the peripheral device in the air close to the notebook PC for convenient use. In the present embodiment, front end 31 of engaging plate 3 is a flat surface. A double-sided duct tape can be used to attach front end 31 of engaging plate 3 to the back of Internet phone. Therefore, the Internet phone can be engaged to or disengaged from the connection arm through engaging plate 3. The front end of engaging plate 3 is not limited to the above embodiment as long as engaging plate 3 can be attached to a peripheral.

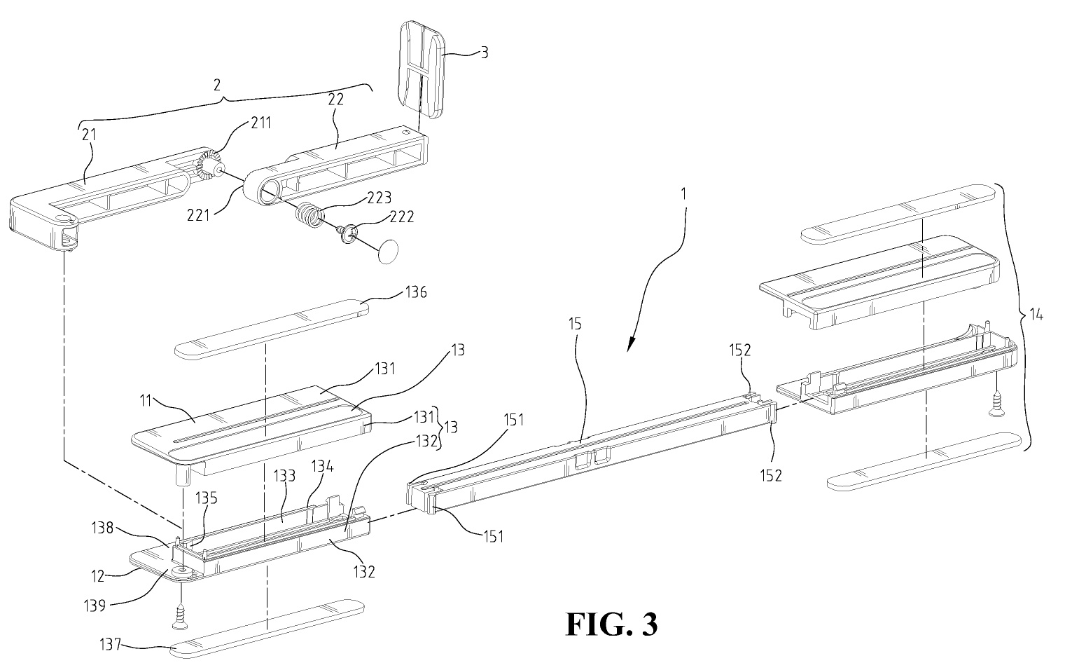

FIG. 3 shows an exploded view of the present invention. As shown in FIG. 3, retractable pad 1 includes a fixed block 13, a fixed block 14, and a connecting element 15. Fixed blocks 13, 14 are of the similar shape, and fixed block 13 is used for description. Fixed block 13 includes a first box seat 131, and a second box seat 132 so that the inside of fixed block 13 forms a housing space 133. The side of housing space 133 is open to the outside so that the left end of connecting element 15 can extend into housing space 133 to achieve the retractility. A plurality of fixed protruding blocks 134, 135 are located close to the two ends on the side wall. Top contact surface 11 of housing space 133. The distance between fixed protruding blocks 134, 135 is the movement range of the left end of connecting element 15. Fixed block 13 includes a top contact surface 11 and a bottom contact surface 12. Contact surfaces 11 12 are not parallel to each other. Top contact surface 11 is engaged to the top surface of first box seat 131 through anti-slip plate 136, and bottom contact surface 12 is engaged to the bottom surface of second surface of second box seat 132 through anti-slip plate 137, so that the notebook PC will not slide on retractable pad 1. As shown in FIGS. 3 & 4, the vertical surface of fixed block 13 forms a concave space 138. The location of concave 138 is parallel to the movement direction of connecting element 15 so that part of connection arm 2 can be stored inside concave space 138. Up to this point, fixed block 13 and fixed block 14 are identical. However, there exist slight difference between fixed block 13 and fixed block 14. The side of fixed block 13 forms a concave joint space 139 connected to concave space 138 to form an L-shaped space. Concave joint space 139 provides the space for first connection rod 21 of connection arm 2 to link and turn, as well as the space for housing first connection rod 21 when stored. The two ends of connecting element 15 extend into the inside of two fixed blocks 13, 14 respectively when assembled so that fixed blocks 13, 14 are located on the two sides of connecting element 15 respectively. By adjusting the distance between two fixed blocks 13, 14, the present invention can be adjusted to fit notebook PCs of different sizes. Each end of connecting element 15 includes a resilient stop stripe 151, 152. Resilient stop stripe 151, 152 pushes against the side wall of fixed blocks 13, 14 when assembled so as to maintain the tightness between fixed blocks 13, 14 and connecting element 15.

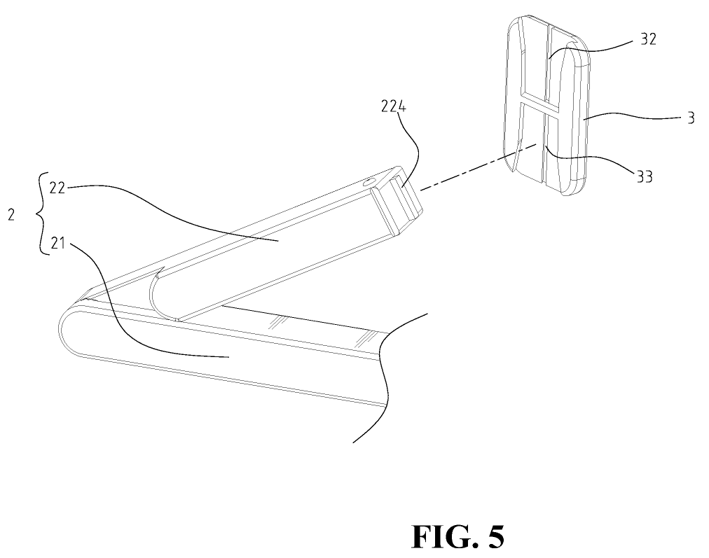

As shown in FIG. 3, connection arm 2 includes a first connection rod 21 and a second connection rod 22, connected to form a supporting arm. In the present embodiment, the L-shaped front end of first connection rod 21 is linked to concave joint space of fixed block 13 of retractable pad 1. The other end of first connection rod 21 is connected to the front end of second connection rod 22. The connected ends of both connection rods include the teeth surface 211, 221 arranged in a ring. The connected ends further include a screw 222 and a spring 223 so that first connection rod 21 and second connection rod 22 can be adjusted and maintain the position and angle. The range of adjustable angle of second connection rod 22 is more than 180°, and is different from the adjustable angle of first connection rod 21. As shown in FIG. 5, the tip of the rear end of second connection rod 22 includes a protruding block 224 of an upside-down trapezoidal shape with the outer side wider than the inner side. The rear surface of engaging plate 3 includes a first trench 32 and a second trench 33. First trench 32 and second trench 33 are able to engage protruding block 224 of second connection rod 22 in various directions.

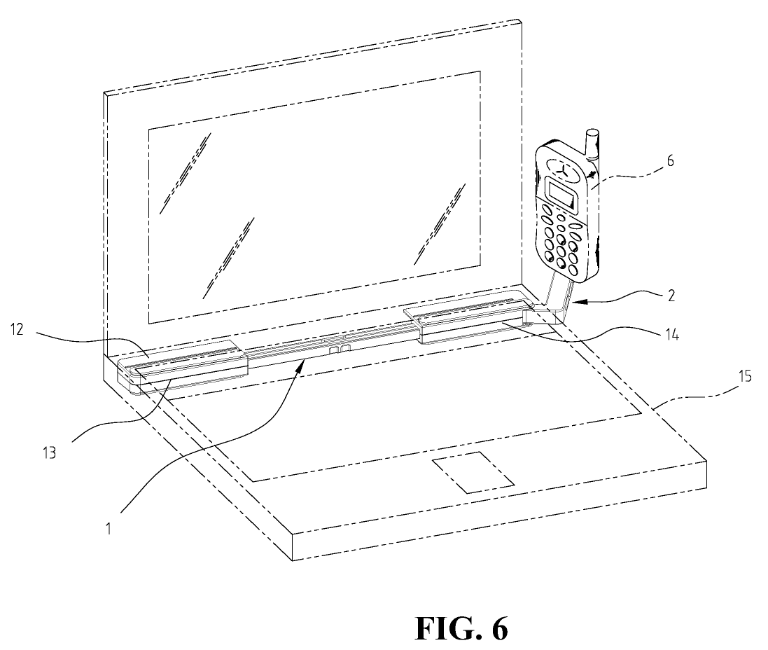

Retractable pad 1 is placed underneath the notebook PC close the rear end where the screen is. However, there is no restriction whether to use contact surface 11 or contact surface 12 for contacting the bottom of the notebook PC. As shown in FIG. 1, if the notebook PC is placed on top contact surface 11, connection arm 2 is located on the left side of the notebook PC. As shown in FIG. 6, if the notebook PC 5 is placed on bottom contact surface 12, connection arm 2 is located on the right side of the notebook PC. The user can choose the placement of the present invention to suit the user's habit. Internet phone 6 is held at the tip of connection arm 2 by engaging plate 3. In the present embodiment, retractable pad 1 uses fixed blocks 13, 14 to adjust to fit notebook PCs of different sizes.

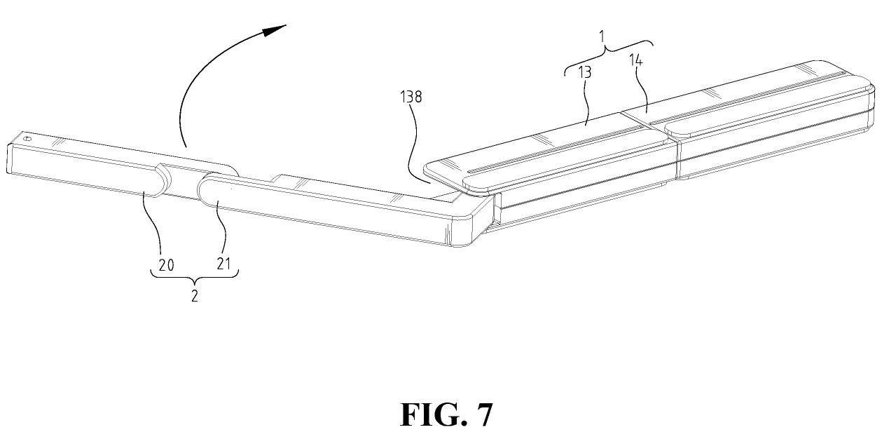

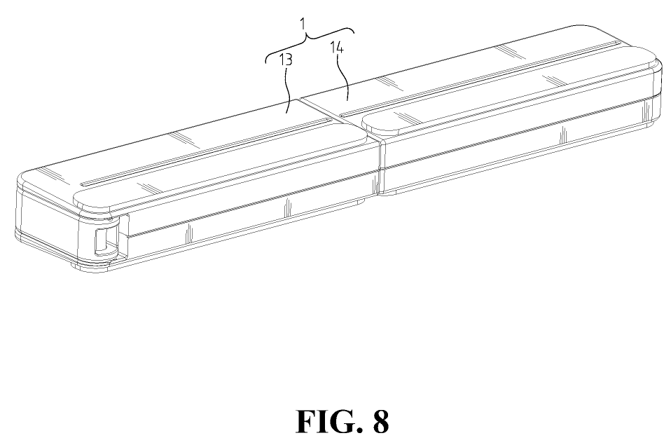

Considering that one of the advantages of notebook PC is the portability, the present invention is also designed to provide portability for convenient use. As shown in FIG. 7, when fixed block 13, 14 of retractable pad 1 are moved towards the center, connecting element 15 is hidden inside fixed blocks 13, 14. Because engaging plate 3 is attached to the back of Internet phone, the Internet phone can be disengaged from the present invention by disengaging engaging plate 3 from connection arm 2. By aligning first connection rod 21 and second connection rod 22 into a straight line, connection arm 2 uses joint as the center to move towards concave housing space 138 behind fixed blocks 13, 14 of retractable pad 1, and can be stored inside space 138. As shown in FIG. 8, the folded size of the present invention is the length of two fixed blocks 13, 14. Therefore, the present invention can be folded for portability.

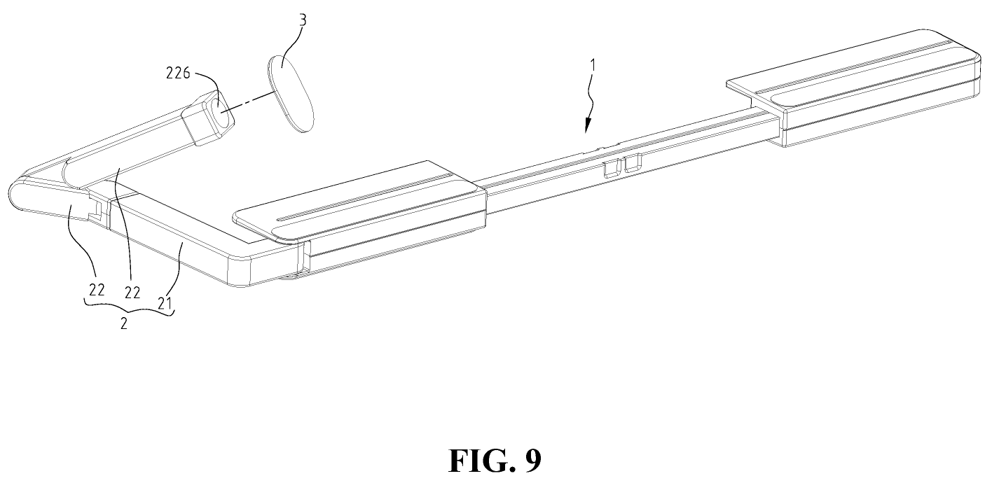

FIG. 9 shows the second embodiment of the present invention. As shown in FIG. 9, the second embodiment includes a different structure of connection arm 2, and the different engagement between connection arm 2 and engaging plate 3. Connection arm 2 of the second embodiment uses three connection rods, including first connection rod 21, second connection rod 22 and third connection rod 23. Third connection rod is connected between first connection rod 21 and second connection rod 22 so as to provide more adjustment possibility. Engaging plate 3 of this embodiment is a metal plate, and the tip of second connection rod 22 includes a magnet 226 so that the engagement between engaging plate 3 and connection arm 2 is different from the first embodiment. Engaging plate 3 also uses double-sided duct tape to be attached to the back of the Internet phone.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An auxiliary pad for notebook PC, comprising:
a retractable pad, having a long shape with a top contact surface and a bottom contact surface, said top contact surface not parallel to said bottom contact surface so that when said retractable pad being placed horizontally, said top contact surface tilting a small angle;
a connection arm, jointing to the side of said retractable pad, further comprising a plurality of connection rods joined together; and
an engaging plate, able to be engaged to or disengaged from the tip of said connection arm.

2. The auxiliary pad as claimed in claim 1, wherein said retractable pad further comprises two fixed blocks and a connecting element, said fixed blocks are located on the two ends of said connecting element, said fixed blocks can move on the said connecting element, said fixed blocks have a top contact surface and a bottom contact surface, and said top contact surface is not parallel to said bottom contact surface.

3. The auxiliary pad as claimed in claim 2, wherein the inside of said fixed block further forms a housing space, the side of said housing space is connected to the outside so that one end of said connecting element is inside said housing space, a resilient stop stripe is located on each side of said end of said connecting element, said resilient stop stripe pushes against the side wall of said housing space to maintain the tightness between said fixed blocks and said connecting element, the side wall of said housing space inside said fixed blocks comprises a plurality of protruding blocks to restrict the movement range of said end of said connecting element.

4. The auxiliary pad as claimed in claim 2, the vertical surface of said fixed blocks comprises a concave housing space parallel to the movement direction of said connecting element so that said connection arm can be folded and hidden inside said concave housing space for storage.

5. The auxiliary pad as claimed in claim 1, wherein said top contact surface is for contacting the bottom of said notebook PC when said retractable pad is placed horizontally.

6. The auxiliary pad as claimed in claim 1, wherein said contact surface of said retractable pad includes an anti-slip plate placed on the surface.

7. The auxiliary pad as claimed in claim 1, wherein said connection arm comprises a first connection rod and a second connection rod, said first connection rod has an L-shape and is joined to the side of said retractable pad, said first connection rod is joined to said second connection rod, the adjustable angles and direction of said first connection rod are different those of said second connection rod so that said connection arm can be adjusted to form a supporting arm.

8. The auxiliary pad as claimed in claim 7, wherein said joint structure of said first connection rod and said second connection rod allows said second connection rod to turn more than 180°.

9. The auxiliary pad as claimed in claim 7, wherein the tip of said second connection rod can be engaged to said engaging plate, said tip of said second connection rod comprises a protruding block, the back of said engaging plate comprises a trench, said protruding block can be engaged to said trench for engagement.

10. The auxiliary pad as claimed in claim 7, wherein the tip of said second connection rod comprises a magnet, and said engaging plate is a metal plate.

11. The auxiliary pad as claimed in claim 1, wherein said engaging plate is attached to Internet phone, a telephone seat, or other electronic peripheral devices.
